(19) United States
(12) Patent Application Publication
(10) Pub. No.: US 2026/0202265 A1
(43) Pub. Date: Jul. 16, 2026

(54) HEAT FLOW MEASURING APPARATUS AND HEAT FLOW MEASURING METHOD

(71) Applicant: TOPOLOGIC INC., Tokyo (JP)

(72) Inventor: Arata TAKAHASHI, Tokyo (JP)

(21) Appl. No.: 19/134,032

(22) PCT Filed: Dec. 21, 2023
(86) PCT No.: PCT/JP2023/045897

§ 371 Date: May 29, 2025

(30) Foreign Application Priority Data
Dec. 27, 2022 (JP) 2022-210990

(51) Int. Cl. G01K 17/00; H10N 19/00

(52) U.S. Cl. CPC G01K 17/00; H10N 19/00

(57) ABSTRACT

A heat flow measuring apparatus is provided. This heat flow measuring apparatus comprises: a thermoelectric conversion unit that is configured to convert, on the basis of the anomalous Nernst effect, a heat gradient generated by heat exchange with an object to be measured into an electric signal; and a magnetic field application unit that is configured to apply a magnetic field in a given direction to the thermoelectric conversion unit.

### CROSS REFERENCE TO RELATED APPLICATIONS

This application is a 371 U.S. National Phase of International Application No. PCT/JP2023/045897, filed on Dec. 21, 2023, which claims priority to Japanese Patent Application No. 2022-210990, filed Dec. 27, 2022. The entire disclosures of the above applications are incorporated herein by reference.

### BACKGROUND

### Technical Field

The present invention relates to a heat flow measuring apparatus and heat flow measuring method.

### Related Art

Japanese Unexamined Patent Application Publication No. 2019-086490 discloses a technology related to a humidity detection device that is more responsive and less susceptible to condensation than conventional humidity detection devices.

The humidity detection device described in Japanese Unexamined Patent Application Publication No. 2019-086490 includes a heat flow sensor disposed on a side wall surface of a gas-liquid separator that forms an internal space through which a fuel off-gas circulates and a hydrophilic sheet for forming a liquid film on a surface of the heat flow sensor. The humidity detection device includes a detection unit that detects the humidity of the fuel off-gas on the basis of an output signal from the heat flow sensor.

A signal indicating a heat gradient detected by a heat flow sensor or the like is weak compared to a signal directly indicating a temperature detected by a thermometer or the like. For this reason, there is still room for improvement in the use of such a heat gradient-related signal in various terms such as the effect of noise and the size.

### SUMMARY

One aspect of the present invention provides a heat flow measuring apparatus (device). This heat flow measuring apparatus includes a thermoelectric conversion unit configured to convert a heat gradient generated by heat exchange with an object to be measured into an electrical signal, on the basis of the anomalous Nernst effect and a magnetic field application unit configured to apply a magnetic field in a given direction to the thermoelectric conversion unit.

Such a configuration makes it possible to provide a method or the like that can more suitably use the signal indicating the detection result of the heat gradient.

### BRIEF DESCRIPTION OF THE DRAWINGS

FIG. 1 is a diagram showing an overview of a heat flow measuring system 1 according to an aspect.

FIG. 2 is a schematic side view of a heat flow measuring device 2 according to a first embodiment.

FIG. 3 is a schematic plan view of a thermoelectric conversion unit 22.

FIG. 4 is a schematic plan view of a first thermoelectric conversion device 22a.

FIG. 5 is a schematic side view of a heat flow measuring device 2A according to a second embodiment.

FIGS. 6A and 6B are schematic back views of the heat flow measuring device 2A according to the second embodiment.

FIG. 7 is a schematic side view of a heat flow measuring device 2B according to a third embodiment.

FIGS. 8A and 8B are schematic back views of the heat flow measuring device 2B according to the third embodiment.

FIG. 9 is a schematic side view of a heat flow measuring device 2C according to a fourth embodiment.

FIGS. 10A and 10B are schematic back views of the heat flow measuring device 2C according to the fourth embodiment.

FIG. 11 is a schematic side view of the heat flow measuring device 2 according to the first embodiment in which an insulator 21 is omitted.

FIGS. 12A to 12C are schematic side views of a heat flow measuring device 2D according to a fifth embodiment.

FIG. 13 is a schematic plan view of a heat flow measuring device 2E according to a sixth embodiment.

FIG. 14 is a block diagram showing the hardware configuration of an information processing device 4.

FIG. 15 is a diagram showing an example of functional units included in a processor 43.

FIG. 16 is an activity diagram showing an example of the flow of information processing performed by the heat flow measuring system 1.

### DETAILED DESCRIPTION

Now, an embodiment of the present invention will be described with reference to the drawings. Various features described in the present embodiment can be combined with each other.

A program to implement software in the present embodiment may be provided as a computer-readable non-transitory storage medium, or may be provided by download from an external server. The program may also be provided such that it is run on an external computer and its functions are implemented on a client terminal (so-called cloud computing).

The term “unit” in the present embodiment includes, for example, a combination of hardware resources implemented by a circuit in a broad sense and software information processing that can be specifically performed by the hardware resources. Various types of information handled in the present embodiment are represented by, for example, the physical values of signal values representing voltages or currents, high or low signal values as binary bit sets consisting of Os or is, or quantum superpositions (so-called qubits) and can be transmitted and subjected to a calculation on a circuit in a broad sense.

The term “circuit in a broad sense” refers to a circuit implemented by combining at least a circuit, circuitry, a processor, memory, and the like appropriately. Specifically, the term “circuit in a broad sense” includes an application-specific integrated circuit (ASIC), programmable logic devices (e.g., a simple programmable logic device (SPLD), a complex programmable logic device (CPLD), a field programmable gate array (FPGA)), and the like.

### 1. Overview of Heat Flow Measuring System 1

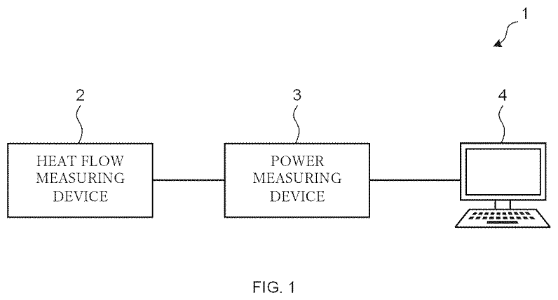

This section describes an overview of a heat flow measuring system 1 according to one aspect. FIG. 1 is a diagram showing an overview of the heat flow measuring system 1.

As shown in FIG. 1, the heat flow measuring system 1 includes a heat flow measuring device 2, a power measuring device 3, and an information processing device 4.

### <Heat Flow Measuring Device 2>

The heat flow measuring device 2 is configured to measure a heat flow. The heat flow measuring device 2 typically measures the flow of heat emitted from an object to be measured. Specifically, the heat flow measuring device 2 measures the heat flow by converting a heat gradient (temperature gradient) generated by heat exchange with the object to be measured or the surrounding environment into electric power. The term “heat exchange” refers to the inflow of heat from the object to be measured or the surrounding environment to the heat flow measuring device 2 and the outflow of heat from the heat flow measuring device 2 to the object to be measured or the surrounding environment. The heat flow measuring device 2 is configured to output a thermoelectromotive force on the basis of the heat gradient. The object to be measured does not have to be a solid but may be any object. It may be fluid, such as a liquid or gas.

### First Embodiment

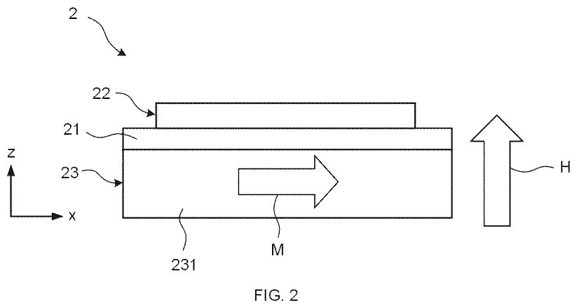

FIG. 2 is a schematic side view of a heat flow measuring device 2 according to a first embodiment. As shown in FIG. 2, the heat flow measuring device 2 includes an insulator 21, a thermoelectric conversion unit 22, and a magnetic field application unit 23.

### <Insulator 21>

The insulator 21 is a layered member having insulation properties. The material of the insulator 21 is, for example, a semiconductor or insulator made of resin, ceramic, or the like. The insulator 21 is a bonding layer that bonds the thermoelectric conversion unit 22 and magnetic field application unit 23 together. For this reason, the insulator 21 is preferably made of a material (e.g., an adhesive) capable of bonding the thermoelectric conversion unit 22 and magnetic field application unit 23 together. Preferably, the material of the insulator 21 has a high thermal conductivity. For example, the insulator 21 preferably has a higher thermal conductivity than the substrate 220 of the thermoelectric conversion unit 22 (to be discussed later). The insulator 21 may have any shape. The insulator 21 may have a curved or bent shape, or may be a so-called flexible substrate, which is deformable.

The thermoelectric conversion unit 22 is disposed on (bonded to) one board surface of the insulator 21. The magnetic field application unit 23 is disposed on (bonded to) the other board surface (i.e., the board surface opposite to the thermoelectric conversion unit 22) of the insulator 21. In other words, the insulator 21 is disposed between the thermoelectric conversion unit 22 and at least one magnet 231 included in the magnetic field application unit 23 (to be discussed later) in the thickness direction of the insulator 21 (a z-direction in FIG. 2). In this way, the thermoelectric conversion unit 22 and the magnet 231 (the magnetic field application unit 23) are bonded together by the insulator 21. That is, the heat flow measuring device 2 can be easily produced.

The heat flow measuring device 2 is disposed such that the thickness direction of the insulator 21 approximately coincides with the direction of a heat flow H.

This increases the heat gradient in the thermoelectric conversion unit 22 and improves the sensitivity of the thermoelectric conversion unit 22.

### <Thermoelectric Conversion Unit 22>

The thermoelectric conversion unit 22 is configured to convert a heat gradient generated by heat exchange with the object to be measured into an electrical signal, on the basis of the anomalous Nernst effect. The thermoelectric conversion unit 22 is a layered (e.g., substrate-shaped) member stacked on the insulator 21.

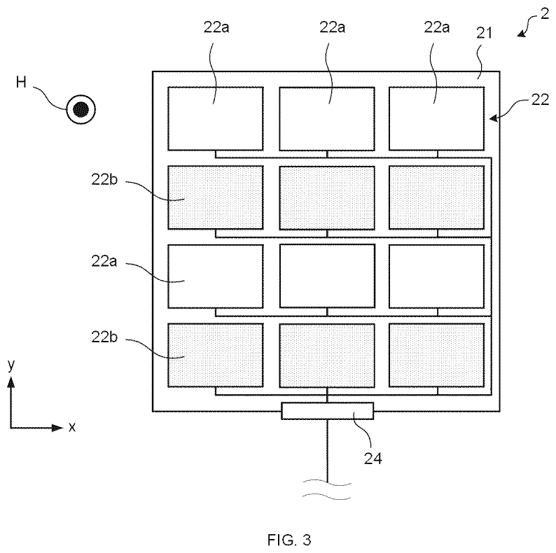

FIG. 3 is a schematic plan view of the thermoelectric conversion unit 22. The thermoelectric conversion unit 22 includes multiple first thermoelectric conversion devices 22a and multiple second thermoelectric conversion devices 22b. Each second thermoelectric conversion device 22b is configured such that the sign of only one of the first thermoelectric force V1 and second thermoelectric force V2 (to be discussed later) generated by the second thermoelectric conversion device 22b on the basis of a heat gradient in approximately the same direction as the direction of the heat gradient of each first thermoelectric conversion device 22a is opposite to the sign of one of the first thermoelectric force V1 and second thermoelectric force V2 generated by the first thermoelectric conversion device 22a on the basis of the heat gradient that corresponds to the only one of the first thermoelectric force V1 and second thermoelectric force V2.

The heat gradient in each of the first thermoelectric conversion devices 22a and second thermoelectric conversion devices 22b includes at least a perpendicular component that is a component along the thickness direction of the insulator 21 (i.e., a component perpendicular to the board surface of the insulator 21 on which the thermoelectric conversion unit 22 is disposed). If the board surface of the insulator 21 is curved, the direction of the perpendicular component of the heat gradient can be defined by the direction of a local normal to the board surface of the insulator 21. For this reason, the direction of the perpendicular component of the heat gradient is not necessarily uniform over the entire area of the insulator 21.

The heat gradient can include an in-plane component that is a component perpendicular to the perpendicular component (i.e., a component parallel to the board surface of the insulator 21 on which the thermoelectric conversion unit 22 is disposed). The in-plane component of the heat gradient can be generated by variations in heat in the in-plane direction of the insulator 21 or variations in heat conduction. If the board surface of the insulator 21 is curved, the direction of the in-plane component of the heat gradient can be defined by a direction perpendicular to a local normal to the board surface of the insulator 21. For this reason, the direction of the in-plane component of the heat gradient is not necessarily uniform over the entire area of the insulator 21.

Note that being “perpendicular” to one direction or plane is not limited to being perfectly perpendicular to the direction or plane and includes, for example, being perpendicular within the allowable error of the dimensions or the like. Similarly, being “parallel” to one direction or plane is not limited to being perfectly parallel to the direction or plane.

The thermoelectromotive forces V outputted by the first thermoelectric conversion devices 22a and second thermoelectric conversion devices 22b can each include the first electromotive force V1 and the second electromotive force V2. The first electromotive force V1 is a thermoelectromotive force generated by a first thermoelectric conversion effect based on the perpendicular component of the heat gradient. The first thermoelectric conversion effect has a generation mechanism different from that of the Seebeck effect and is generated by the anomalous Nernst effect.

For example, the first electromotive force V1 is represented by a quantity depending on a physical variable corresponding to the magnetic field of the off-diagonal elements of the thermoelectric tensor of each of the first thermoelectric conversion devices 22a and second thermoelectric conversion devices 22b. The first thermoelectric force V1 is a quantity that is antisymmetric with respect to the magnetic field, symmetric with respect to the in-plane component of the heat gradient, and antisymmetric with respect to the perpendicular component of the heat gradient. The direction of the first thermoelectric force V1 is approximately perpendicular to the perpendicular component of the heat gradient.

The second electromotive force V2 is a thermoelectromotive force generated by a second thermoelectric conversion effect based on the in-plane component of the heat gradient. The second thermoelectric conversion effect has a generation mechanism different from that of the first thermoelectric conversion effect and is generated by the diagonal elements of the thermoelectric tensor of the Seebeck effect or the like. For example, the second electromotive force V2 is represented by a quantity depending on a physical variable corresponding to the heat gradient of the diagonal elements of the thermoelectric tensor of each of the first thermoelectric conversion devices 22a and second thermoelectric conversion devices 22b. The second thermoelectric force V2 is a quantity that is antisymmetric with respect to the heat gradient. The direction of the second thermoelectric force V2 is approximately parallel to the direction of the in-plane component of the heat gradient. Thus, when the in-plane component of the heat gradient is parallel to the direction of the first thermoelectric force V1, the direction of the second thermoelectric force V2 is approximately parallel to the direction of the first thermoelectric force V1.

As shown in FIG. 3, the first thermoelectric conversion devices 22a and second thermoelectric conversion devices 22b are disposed on the same board surface of the single insulator 21. In an example in FIG. 3, the first thermoelectric conversion devices 22a and second thermoelectric conversion devices 22b are disposed in an x-direction, respectively, and are disposed in a y-direction alternately. This allows for, for example, a reduction in measurement errors caused by fluctuations in the in-plane component of the heat gradient on the board surface of the insulator 21. The first thermoelectric conversion devices 22a and second thermoelectric conversion devices 22b are connected in parallel by wiring.

The first thermoelectric conversion devices 22a and second thermoelectric conversion devices 22b may be disposed in any form. For example, the first thermoelectric conversion devices 22a and second thermoelectric conversion devices 22b may be disposed on different insulators 21. The first thermoelectric conversion devices 22a and second thermoelectric conversion devices 22b may also be electrically insulated from each other. These suppress fluctuations in the thermoelectromotive forces V outputted from the thermoelectric conversion devices due to noise. Moreover, the first thermoelectric conversion devices 22a may be connected in series with each other. The second thermoelectric conversion devices 22b may also be connected in series with each other. These increase the first electromotive forces V1 and second electromotive forces V2 included in the thermoelectromotive forces V of the thermoelectric conversion devices connected in series. Furthermore, the first thermoelectric conversion devices 22a and second thermoelectric conversion devices 22b may be connected in series.

In the present aspect, both the first thermoelectric conversion devices 22a and second thermoelectric conversion devices 22b do not necessarily have to be used. In other words, the thermoelectric conversion unit 22 may include only the first thermoelectric conversion devices 22a.

<First Thermoelectric Conversion Device 22a>

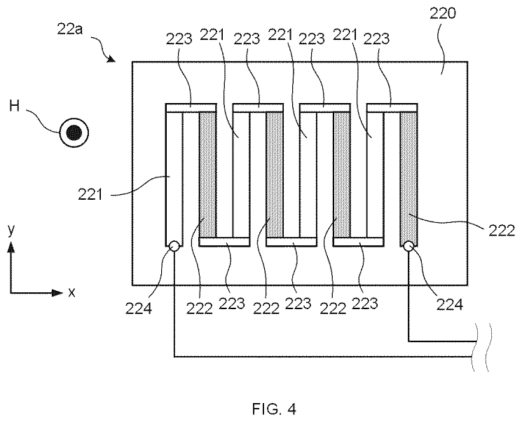

The configuration of the first thermoelectric conversion devices 22a will be described below. The configuration of the second thermoelectric conversion devices 22b is the same as that of the first thermoelectric conversion devices 22a except for points to be described later. FIG. 4 is a schematic plan view of a first thermoelectric conversion device 22a. As shown in FIG. 4, the first thermoelectric conversion device 22a includes a substrate 220, multiple thermoelectric conversion elements 221, multiple first conductors 222, multiple second conductors 223, and multiple measuring terminals 224.

### <Substrate 220>

The substrate 220 is stacked on the board surface of the insulator 21. The plane area of the substrate 220 is smaller than the plane area of the insulator 21. The substrate 220 may be formed integrally with the insulator 21. The material of the substrate 220 is, for example, a semiconductor such as silicon or MgO, or insulator.

### <Thermoelectric Conversion Element 221>

The thermoelectric conversion elements 221 are configured to generate the anomalous Nernst effect. The thermoelectric conversion elements 221 may be made of, for example, a topological ferromagnetic or topological antiferromagnetic material called Weyl semimetal, a ferrimagnetic material, or a combination thereof. The topological ferromagnetic material may be a metal with a composition Co2TX (where X represents any one of Si, Ge, Sn, Al, and Ga), such as Co2MnGa, or may be an alloy of a known topological ferromagnetic material, such as a metal with a composition formula Fe3X (where X represents a typical element such as Al or Ga, or a transition element) (a stoichiometric or off-stoichiometric composition). The topological antiferromagnetic material may be a known topological antiferromagnetic material such as Mn3X (where X represents one or more elements selected from Sn, Ge, Ga, Pt, Ir, and Rh, or a compound of these). The alloy constituting the topological ferromagnetic material or topological antiferromagnetic material does not necessarily have to have a stoichiometric composition ratio as described above. The alloy may have any composition ratio as long as it has a partially stoichiometric structure. The ferrimagnetic material may be of any type as long as it generates the anomalous Nernst effect. The thermoelectric conversion elements 221 may generate the anomalous Nernst effect, for example, by having a crystal structure with Kagome lattice planes made of a transition metal. The thermoelectric conversion elements 221 may have any structure, and known structures can be used.

Typically, the thermoelectric conversion elements 221 contain a magnetic material having a magnetic structure capable of generating the anomalous Nernst effect. The magnetic structure may be any of an antiferromagnetic structure, a canted antiferromagnetic structure, a ferrimagnetic structure, a ferromagnetic structure, and a weak ferromagnetic structure (an antiferromagnetic magnetic order with spontaneous magnetization), as long as it is able to generate the anomalous Nernst effect. The magnetic structure of the magnetic material includes at least one of a first magnetic structure and a second magnetic structure formed to be time-reversal symmetric with respect to the first magnetic structure.

As described above, the thermoelectric conversion elements 221 may be made of any material as long as the material is able to generate the anomalous Nernst effect. The thermoelectric conversion elements 221 of the first thermoelectric conversion devices 22a and the thermoelectric conversion elements 221 of the second thermoelectric conversion devices 22b consist of approximately the same compositions capable of generating the anomalous Nernst effect. Examples of the compositions capable of generating the anomalous Nernst effect include Mn3Sn, Mn3Ge, Mn3Ga, Co3MnGa, Fe3Al, Fe3Ga, Fe3Sn, and alloys, elemental substitutes, or mixtures thereof. The anomalous Nernst effect generation mechanism may be any mechanism. One example is a mechanism originating from an antiferromagnetic magnetic structure with a non-collinear spin structure. Such a mechanism tends to have a larger Nernst coefficient than other generation mechanisms. This facilitates more precise measurement, downsizing of the device, and the like. The thermoelectric conversion elements 221 may be embodied as polycrystals or monocrystals of the above materials. It is only necessary that the crystallographic domain of the monocrystals be uniform to the extent that asymmetric physical properties due to a reduction in symmetry associated with the generation of a magnetic order are observed.

In the present aspect, the thermoelectric conversion elements 221 are formed as thin films having a thickness in a direction perpendicular to a board surface of the substrate 220. Forming the thermoelectric conversion elements 221 as thin films makes the contribution of magnetic anisotropy greater than that of other factors. This makes the easy axis of magnetization and the spin easy axis more likely to extend in a direction along the board surface of the substrate 220. Thus, it becomes easy to properly adjust the direction of the first electromotive force V1 generated by the anomalous Nernst effect. The thermoelectric conversion elements 221 may have any thickness. Specifically, for example, the thickness may be 5, 6, 7, 8, 9, 10, 20, 30, 40, 50, 60, 70, 80, 90, 100, 200, 300, 400, 500, 600, 700, 800, or 900 nm or may be in the range between any two of the values illustrated above. The thermoelectric conversion elements 221 may be mounted on the substrate 220 using an any method. Examples of the mounting method include physical vapor deposition such as sputtering and ion plating, plating, chemical vapor deposition, molecular beam epitaxial growth (MBE), sintering of the powder of the above compounds, various types of printing such as inkjet printing using liquid drops obtained by dissolving the above compounds, and three-dimensional printing using the above compounds. The thermoelectric conversion elements 221 may be mounted using a method similar to the method for mounting the first conductors 222 and the second conductors 223. This simplifies the process of producing the heat flow measuring device 2. The thermoelectric conversion elements 221 included in one first thermoelectric conversion device 22a may contain the same magnetic material or different magnetic materials.

The thermoelectric conversion elements 221 extend linearly along the direction in which the first electromotive force V1 is generated (the y-direction in an example in FIG. 4) in a plan view. In other words, the thermoelectric conversion elements 221 are each formed on the substrate 220 in the form of a strip having a longitudinal direction parallel to the direction in which the first electromotive force V1 is generated. The direction in which the first thermoelectric force V1 is generated is the direction in which the anomalous Nernst effect based on the perpendicular component of the heat gradient is generated to the greatest extent. The central axis (the longitudinal direction) of each thermoelectric conversion element 221 in a plan view may be curved or bent.

The first thermoelectric conversion devices 22a and second thermoelectric conversion devices 22b are oriented such that the longitudinal directions of the respective thermoelectric conversion elements 221 become parallel to each other. This reduces the discrepancy between the first electromotive forces V1 generated by each first thermoelectric conversion device 22a and each second thermoelectric conversion device 22b due to the anomalous Nernst effect based on the perpendicular component of the heat gradient. This facilitates separation of the contributions of the first electromotive force V1 and second electromotive force V2 included in each thermoelectromotive force V.

Each first thermoelectric conversion device 22a and each second thermoelectric conversion device 22b may include any number of thermoelectric conversion elements 221. The number of thermoelectric conversion elements 221 included in each first thermoelectric conversion device 22a may be the same as or different from the number of thermoelectric conversion elements 221 included in each second thermoelectric conversion device 22b. The number of thermoelectric conversion elements 221 included in each first thermoelectric conversion device 22a and the number of thermoelectric conversion elements 221 included in each second thermoelectric conversion device 22b are selected such that the discrepancy between the second electromotive force V2 generated by one whole first thermoelectric conversion device 22a and the second electromotive force V2 generated by one second thermoelectric conversion device 22b becomes smaller than required measurement accuracy.

The sign of the Nernst coefficient of the thermoelectric conversion elements 221 of each first thermoelectric conversion device 22a is different from that of the thermoelectric conversion elements 221 of each second thermoelectric conversion device 22b. In other words, the polarity of the thermoelectric conversion elements 221 of each first thermoelectric conversion device 22a is different from that of the thermoelectric conversion elements 221 of each second thermoelectric conversion device 22b. For this reason, the sign of the first electromotive forces V1 generated by the thermoelectric conversion elements 221 of each first thermoelectric conversion device 22a on the basis of a certain heat gradient is different from the sign of the first electromotive forces V1 generated by the thermoelectric conversion elements 221 of each second thermoelectric conversion device 22b on the basis of the same heat gradient (that is, the signs are opposite). On the other hand, the sign of the first electromotive forces V1 generated by the thermoelectric conversion elements 221 of each first thermoelectric conversion device 22a on the basis of this heat gradient and the sign of the second electromotive forces V2 generated by the thermoelectric conversion elements 221 of each second thermoelectric conversion device 22b on the basis of this heat gradient are the same. This is because the respective signs are defined by the direction of the in-plane component of the heat gradient.

Such opposite polarities related to the anomalous Nernst effect of the first thermoelectric conversion device 22a and second thermoelectric conversion device 22b are achieved, for example, by reversing the polarity of the magnetic structure of the magnetic material contained in the thermoelectric conversion elements 221 (for example, the direction of spontaneous magnetization of the magnetic material) or the sign of the Nernst coefficient specific to the material contained in the thermoelectric conversion elements 221.

The magnetic material of the thermoelectric conversion elements 221 of the first thermoelectric conversion devices 22a is configured such that the ratio of a magnetic domain corresponding to the second magnetic structure to a magnetic domain corresponding to the first magnetic structure is greater than one. The magnetic material of the thermoelectric conversion elements 221 of the second thermoelectric conversion devices 22b is configured such that the ratio of the magnetic domain corresponding to the second magnetic structure to the magnetic domain corresponding to the first magnetic structure is smaller than one. In other words, in the thermoelectric conversion elements 221 of the first thermoelectric conversion devices 22a and second thermoelectric conversion devices 22b, the sign of the components of the thermoelectric tensor corresponding to the anomalous Nernst effect generated by the first magnetic structure is different from the sign of the components of the thermoelectric tensor corresponding to the anomalous Nernst effect generated by the second magnetic structure. Thus, the thermoelectric conversion elements 221 of each second thermoelectric conversion device 22b are configured such that the sign of the first thermoelectric forces V1 generated by the thermoelectric conversion elements 221 of the second thermoelectric conversion device 22b on the basis of a heat gradient in approximately the same direction as the direction of the heat gradient of each first thermoelectric conversion device 22a is opposite to the sign of the first thermoelectric forces V1 generated by the thermoelectric conversion elements 221 of the first thermoelectric conversion device 22a on the basis of the heat gradient. In such a magnetic structure, spontaneous magnetization occurs along the easy axis of magnetization. If the magnetic material is a ferromagnetic material or ferrimagnetic material, the easy axis of magnetization is approximately parallel to the spin easy axis. If the magnetic material is a canted antiferromagnetic material, the easy axis of magnetization intersects the spin easy axis (for example, the easy axis of magnetization is perpendicular to the spin easy axis). The magnetic structure of each first thermoelectric conversion device 22a differs in polarity from that of each second thermoelectric conversion device 22b. For this reason, the direction of the magnetic domain of each first thermoelectric conversion device 22a is opposite to the direction of the magnetic domain of each second thermoelectric conversion device 22b. In the present embodiment, the thermoelectric conversion elements 221 contain a ferrimagnetic material, and the easy axis of magnetization thereof intersects the longitudinal direction of the thermoelectric conversion elements 221 and is parallel to the board surface of the insulator 21.

### <First Conductor 222 and Second Conductor 223>

The first conductors 222 and second conductors 223 connect the thermoelectric conversion elements 221 in series with each other to increase the first electromotive forces V1 of the thermoelectric conversion elements 221.

The first conductors 222 extend linearly along the longitudinal direction of the thermoelectric conversion elements 221 in a plan view. In other words, the first conductors 222 are each formed on the substrate 220 in the shape of a strip having a longitudinal direction parallel to the longitudinal direction of the thermoelectric conversion elements 221. The first conductors 222 are each disposed between two thermoelectric conversion elements 221 in the width direction of the thermoelectric conversion elements 221.

The second conductors 223 each electrically connect an end of one thermoelectric conversion element 221 and an end of a first conductor 222 adjacent to this thermoelectric conversion element 221. The second conductors 223 extend linearly along the width direction of the thermoelectric conversion elements 221 in a plan view. In other words, the second conductors 223 are each formed on the substrate 220 in the shape of a strip having a longitudinal direction parallel to the width direction of the thermoelectric conversion elements 221.

In each first thermoelectric conversion device 22a, the first conductors 222 and second conductors 223 form a meander structure in which the thermoelectric conversion elements 221 and first conductors 222 are alternately disposed. Note that the thermoelectric conversion elements 221, first conductors 222, and second conductors 223 may be connected in any form. Moreover, the first conductors 222 and second conductors 223 may be formed in any manner. For example, the first conductors 222 and second conductors 223 may be formed by sputtering a metal onto the substrate 220, or may be laminated on the substrate 220 and then connected to the thermoelectric conversion elements 221 using leads.

### <Measuring Terminal 224>

The measuring terminals 224 constitute the terminals of an electrical circuit including the thermoelectric conversion elements 221 formed in the first thermoelectric conversion device 22a. In an example in FIG. 4, one measuring terminal 224 is electrically connected to an end of a thermoelectric conversion element 221, and another measuring terminal 224 is electrically connected to an end of a first conductor 222.

The measuring terminals 224 may be physical connection terminals such as pins, tabs, or ribbon terminals, or virtual terminals serving as points at which the thermoelectromotive forces V are measured. The thermoelectromotive forces V outputted from the thermoelectric conversion elements 221 connected in series by the first conductors 222 and second conductors 223 are acquired through the two measuring terminals 224. The measuring terminals 224 of each first thermoelectric conversion device 22a are electrically insulated from the measuring terminals 224 of the other first thermoelectric conversion devices 22a or the second thermoelectric conversion devices 22b. This reduces the contact resistance of each first thermoelectric conversion device 22a and thus improves the accuracy of measurement of the thermoelectromotive force V.

### <Port 24>

As shown in FIG. 3, the heat flow measuring device 2 further includes a port 24. The port 24 allows the first thermoelectric conversion devices 22a and second thermoelectric conversion device 22b to be electrically connected to an external device (power measuring device 3).

In an example in FIG. 3, the port 24 is electrically connected to the measuring terminals 224 of the first thermoelectric conversion devices 22a and second thermoelectric conversion devices 22b. Any wiring may be interposed between the measuring terminals 224 and the port 24. By connecting the port 24 to the external device such as the power measuring device 3, signals related to the thermoelectromotive forces V outputted from the first thermoelectric conversion devices 22a and second thermoelectric conversion devices 22b (specifically, the measuring terminals 224 thereof) are transmitted to the external device. The external device can performs various processes on the basis of the signals outputted from the heat flow measuring device 2.

In the example in FIG. 3, the port 24 is formed to comprehensively receive wiring extending from each of the measuring terminals 224. This makes the wiring for connecting with the external device simpler. The port 24 may be, for example, a multi-channel port capable of transmitting the thermoelectromotive forces V outputted from the measuring terminals 224 as independent signals.

In the thermoelectric conversion unit 22, when the thermoelectromotive force V generated by each first thermoelectric conversion device 22a on the basis of a certain heat gradient is +V1+V2, the thermoelectromotive force V generated by each second thermoelectric conversion device 22b on the basis of the same temperature gradient is −V1+V2. That is, the direction of the first electromotive force V1 generated on the basis of the anomalous Nernst effect is reversed. For this reason, by comparing the thermoelectromotive force V generated by each first thermoelectric conversion device 22a and the thermoelectromotive force V generated by each second thermoelectric conversion device 22b, the components of each thermoelectromotive force V based on the heat gradient, such as the first electromotive force V1 and second electromotive force V2, can be separated more accurately.

### <Magnetic Field Application Unit 23>

As shown in FIG. 2, the magnetic field application unit 23 is disposed on the board surface opposite to the thermoelectric conversion unit 22 of the insulator 21. The magnetic field application unit 23 is configured to apply a magnetic field in a given direction to the thermoelectric conversion unit 22. Such a magnetic field provided by the magnetic field application unit 23 suppresses changes in the sensitivity of the heat gradient due to the magnetization of the thermoelectric conversion unit 22 caused by a disturbing magnetic field. This reduces the effect of noise on the thermoelectric conversion unit 22 and improves the accuracy of detection of a heat flow. Preferably, the material of the magnetic field application unit 23 has a high thermal conductivity.

The magnetic field application unit 23 includes at least one magnet 231 stacked on the thermoelectric conversion unit 22. Thus, the magnetic field application unit 23 and the thermoelectric conversion unit 22 are integrated. This downsizes the heat flow measuring device 2 and makes it easy to handle the heat flow measuring device 2. The magnet 231 may be a permanent magnet or an electromagnet.

In an example in FIG. 2, one magnet 231 is stacked on the board surface of the insulator 21. Preferably, the plane area of the magnet 231 is equal to or greater than the plane area of the thermoelectric conversion unit 22. In other words, the magnet 231 preferably overlap the entire thermoelectric conversion unit 22 in the thickness direction of the insulator 21. The direction of a magnetic field M generated by the magnet 231 is a direction intersecting the direction of the heat flow H (i.e., the thickness direction of the insulator 21) and is preferably a direction perpendicular to the direction of the heat flow H. Thus, interference by the magnetic field M with the magnetization of the thermoelectric conversion element 221 by the heat flow H is suppressed.

The magnet 231 is formed in the shape of a plate. Specifically, the magnetic field application unit 23 according to the present embodiment is a layered member stacked on the thermoelectric conversion unit 22 in the thickness direction of the thermoelectric conversion unit 22. This reduces the thickness of the heat flow measuring device 2, allowing the heat flow measuring device 2 to be used for various purposes.

The magnetic field application unit 23 may be formed by forming the magnet 231 directly on the board surface of the insulator 21 by, for example, sputtering, evaporation, molecular beam epitaxy (MBE), or the like, or may be formed by bonding the previously formed magnet 231 to the insulator 21 using an adhesive or the like.

### Second Embodiment

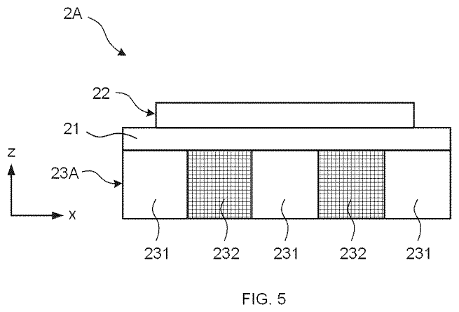

FIG. 5 is a schematic side view of a heat flow measuring device 2A according to a second embodiment. As shown in FIG. 5, the heat flow measuring device 2A includes an insulator 21, a thermoelectric conversion unit 22, and a magnetic field application unit 23A. The insulator 21 and thermoelectric conversion unit 22 of the heat flow measuring device 2A are similar to the insulator 21 and thermoelectric conversion unit 22 of the heat flow measuring device 2 in FIG. 2.

### <Magnetic Field Application Unit 23A>

The magnetic field application unit 23A includes at least one magnet 231 stacked on the thermoelectric conversion unit 22 and at least one high heat conductor 232 aligned with the at least one magnet 231 in an alignment direction. The alignment direction is a direction intersecting the direction in which the magnet 231 is stacked on the thermoelectric conversion unit 22 (i.e., the thickness direction of the insulator 21) and is specifically an x-direction or y-direction perpendicular to the thickness direction of the insulator 21.

The high heat conductor 232 has a higher thermal conductivity than the magnet 231. Thus, the high heat conductor 232 suppresses a reduction in the efficiency of heat exchange with an object to be measured while the magnet 231 applies a magnetic field.

Specifically, the magnetic field application unit 23A includes multiple magnets 231 and multiple high heat conductors 232. The magnets 231 and high heat conductors 232 are disposed alternately in the alignment direction. Thus, both the effect of reducing noise due to the application of the magnetic field and the effect of suppressing a reduction in the heat exchange efficiency are promoted.

The magnets 231 are the same as the magnet 231 in FIG. 2 except for the shape. The high heat conductors 232 may be made of any material as long as the material has a higher thermal conductivity than the magnets 231. The high heat conductors 232 may be formed on the board surface of the insulator 21 together with the magnets 231 by sputtering, vapor deposition, MBE, or the like, or may be bonded to the insulator 21 using an adhesive or the like.

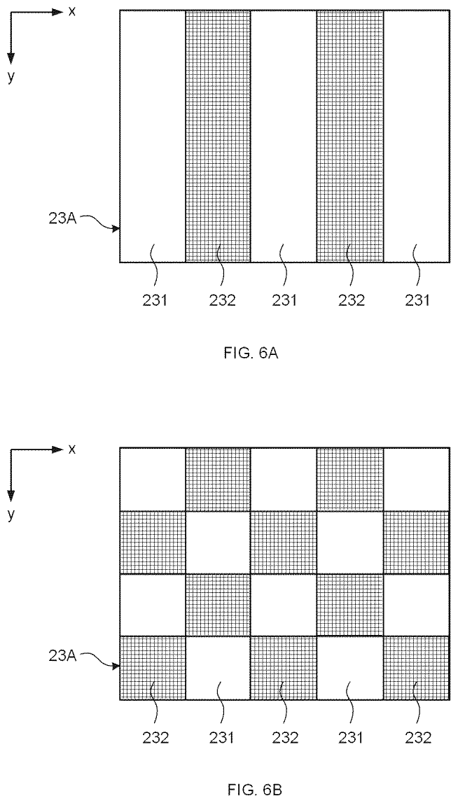

FIGS. 6A and 6B are schematic back views of the heat flow measuring device 2A according to the second embodiment. In an example in FIG. 6A, the strip-shaped magnets 231 and strip-shaped high heat conductors 232 are disposed alternately in the x-direction. Preferably, the direction of the magnetic field M applied by the magnets 231 is parallel to the alignment direction (the x-direction). In an example in FIG. 6B, the magnets 231 and high heat conductors 232 are disposed alternately in the two alignment directions (in both the x- and y-directions). In other words, the magnets 231 and high heat conductors 232 may be disposed in the shape of a block check.

Preferably, the thickness of the magnets 231 and the thickness of the high heat conductors 232 are the same. This flattens the surface opposite to the thermoelectric conversion unit 22 of the heat flow measuring device 2A. However, the thickness of the magnets 231 and the thickness of the high heat conductors 232 may be different. Moreover, the lengths of the magnets 231 and high heat conductors 232 in the x- and y-directions do not have to be the same.

### Third Embodiment

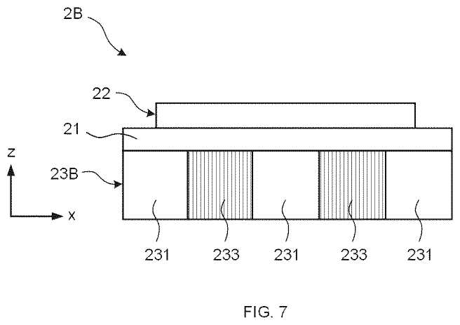

FIG. 7 is a schematic side view of a heat flow measuring device 2B according to a third embodiment. As shown in FIG. 7, the heat flow measuring device 2B includes an insulator 21, a thermoelectric conversion unit 22, and a magnetic field application unit 23B. The insulator 21 and thermoelectric conversion unit 22 of the heat flow measuring device 2B are similar to the insulator 21 and thermoelectric conversion unit 22 of the heat flow measuring device 2 in FIG. 2.

### <Magnetic Field Application Unit 23B>

The magnetic field application unit 23B includes at least one magnet 231 stacked on the thermoelectric conversion unit 22 and at least one soft magnetic portion 233 aligned with the at least one magnet 231 in an alignment direction. The alignment direction is a direction intersecting the direction in which the at least one magnet 231 is stacked on the thermoelectric conversion unit 22 and is specifically an x- or y-direction perpendicular to the thickness direction of the insulator 21. The at least one soft magnetic portion 233 contains a soft magnetic material as a main component. Thus, the soft magnetic portion 233 suppresses a reduction in the efficiency of heat exchange with an object to be measured while the magnet 231 applies a magnetic field.

Specifically, the magnetic field application unit 23B includes multiple magnets 231 and multiple soft magnetic portions 233. The magnets 231 and soft magnetic portions 233 are disposed alternately in the alignment direction. Thus, both the effect of reducing noise due to the application of the magnetic field and the effect of suppressing a reduction in the heat exchange efficiency are promoted.

The magnets 231 are the same as the magnet 231 in FIG. 2 except for the shape. The soft magnetic portions 233 are made of a material with low coercivity and high permeability. Examples of the material of the soft magnetic portions 233 include iron. The soft magnetic portions 233 are able to exchange heat with the object to be measured more efficiently than the magnets 231 while suppressing attenuation of the magnetic field M generated by the magnets 231 by their own magnetization.

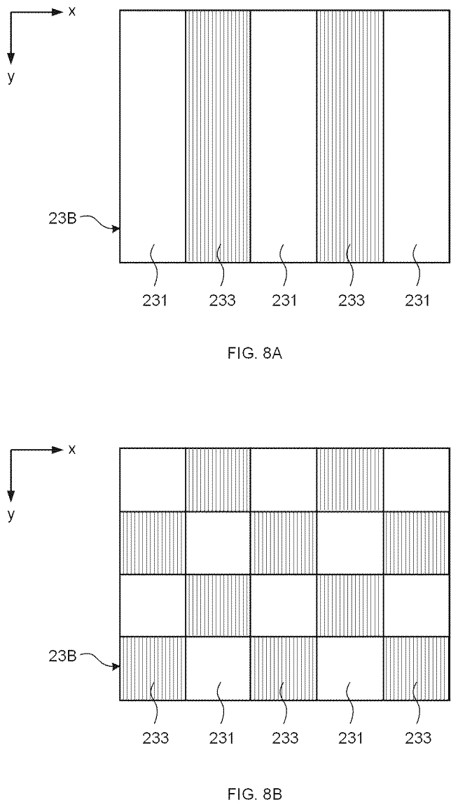

FIGS. 8A and 8B are schematic back views of the heat flow measuring device 2B according to the third embodiment. In an example in FIG. 8A, multiple strip-shaped magnets 231 and multiple strip-shaped soft magnetic portions 233 are disposed alternately in the x-direction. Preferably, the direction of a magnetic field M applied by the magnets 231 is parallel to the alignment direction (the x-direction). In an example in FIG. 8B, multiple magnets 231 and multiple soft magnetic portions 233 are disposed alternately in the two alignment directions (in both the x- and y-directions). That is, the magnets 231 and soft magnetic portions 233 may be disposed in the shape of a block check.

Preferably, the thickness of the magnets 231 and the thickness of the soft magnetic portions 233 are the same. This flattens the surface opposite to the thermoelectric conversion unit 22 of the heat flow measuring device 2B. However, the thickness of the magnets 231 and the thickness of the soft magnetic portions 233 may be different. Moreover, the lengths of the magnets 231 and soft magnetic portions 233 in the x- and y-directions do not have to be the same.

### Fourth Embodiment

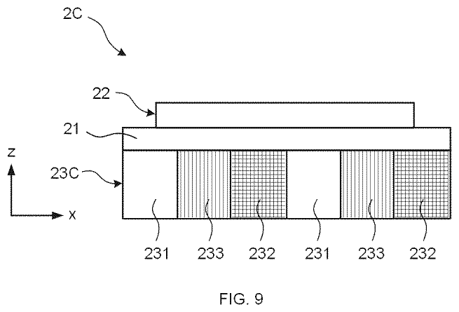

FIG. 9 is a schematic side view of a heat flow measuring device 2C according to a fourth embodiment. As shown in FIG. 9, the heat flow measuring device 2C includes an insulator 21, a thermoelectric conversion unit 22, and a magnetic field application unit 23C. The insulator 21 and thermoelectric conversion unit 22 of the heat flow measuring device 2C are similar to the insulator 21 and thermoelectric conversion unit 22 of the heat flow measuring device 2 in FIG. 2.

### <Magnetic Field Application Unit 23C>

The magnetic field application unit 23C includes at least one magnet 231 stacked on the thermoelectric conversion unit 22, at least one high heat conductor 232 aligned with the at least one magnet 231 in an alignment direction, and at least one soft magnetic portion 233 aligned with the at least one magnet 231 in the alignment direction. The alignment direction is a direction intersecting the direction in which the at least one magnet 231 is stacked on the thermoelectric conversion unit 22 and is specifically an x- or y-direction perpendicular to the thickness direction of the insulator 21. Thus, the high heat conductor 232 and soft magnetic portion 233 suppress a reduction in the efficiency of heat exchange with an object to be measured while the magnet 231 applies a magnetic field.

Specifically, the magnetic field application unit 23C includes multiple magnets 231, multiple high heat conductors 232, and multiple soft magnetic portions 233. The magnets 231, high heat conductors 232, and soft magnetic portions 233 are disposed alternately in the alignment direction. Thus, both the effect of reducing noise due to the application of the magnetic field and the effect of suppressing a reduction in the heat exchange efficiency are promoted.

The magnets 231 are the same as the magnet 231 in FIG. 2 except for the shape. The high heat conductors 232 are the same as the high heat conductors 232 in FIG. 5 except for the shape. The soft magnetic portions 233 are the same as the soft magnetic portions 233 in FIG. 7 except for the shape.

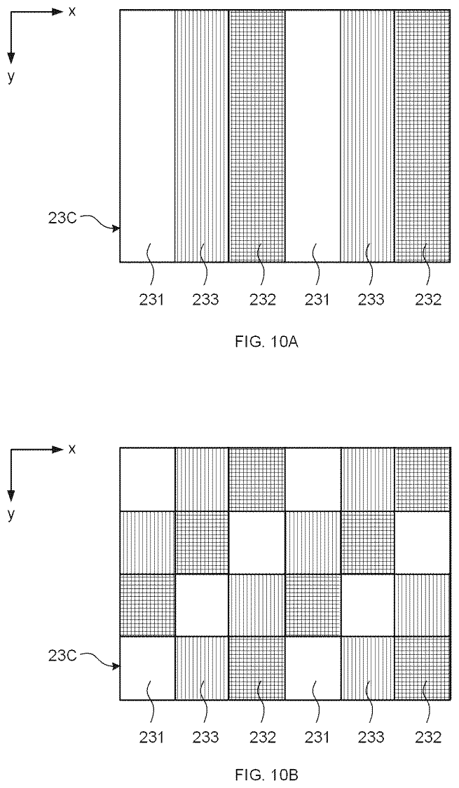

FIGS. 10A and 10B are schematic back views of the heat flow measuring device 2C according to the fourth embodiment. In an example in FIG. 10A, multiple strip-shaped magnets 231, multiple strip-shaped high heat conductors 232, and multiple strip-shaped soft magnetic portions 233 are disposed alternately in the x-direction. Preferably, the direction of a magnetic field M applied by the magnets 231 is parallel to the alignment direction (the x-direction). In FIG. 10A, the magnets 231, high heat conductors 232, and soft magnetic portions 233 and are disposed in a given order, that is, in the order of the magnet 231, soft magnetic portion 233, and high heat conductor 232 from the left. However, this order is not limiting.

In an example in FIG. 10B, the magnets 231, the high heat conductors 232 and soft magnetic portions 233 are disposed alternately in the two alignment directions (in both the x- and y-directions). In other words, the magnets 231, the high heat conductors 232 and soft magnetic portions 233 may be disposed in the shape of a block check. In FIG. 10B, the magnets 231, high heat conductors 232, and soft magnetic portions 233 are disposed in given orders, that is, in the order of the magnet 231, soft magnetic portion 233, and high heat conductor 232 from the left and in the order of the magnet 231, soft magnetic portion 233, and high heat conductor 232 from the top. However, these orders are not limiting.

Preferably, the thickness of the magnets 231, the thickness of the high heat conductors 232, and the thickness of the soft magnetic portions 233 are the same. This flattens the surface opposite to the thermoelectric conversion unit 22 of the heat flow measuring device 2C. However, the thickness of the magnets 231, the thickness of the high heat conductors 232, and the thickness of the soft magnetic portions 233 may be different. The lengths of the magnets 231, high heat conductors 232, and soft magnetic portions 233 in the x- and y-directions do not have to be the same.

### <Modifications of First to Forth Embodiments>

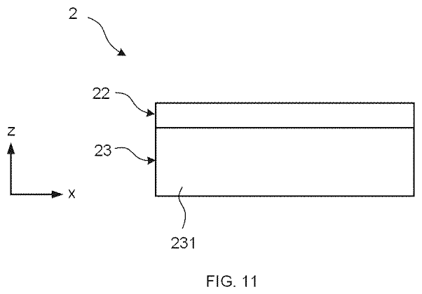

In the first to fourth embodiments, the insulator 21 of the heat flow measuring device 2 may be omitted. FIG. 11 is a schematic side view of the heat flow measuring device 2 according to the first embodiment in which the insulator 21 is omitted. The insulator 21 is omitted, for example, by forming the magnetic field application unit 23 directly on the substrates 220 of the thermoelectric conversion unit 22 by sputtering or the like. The same applies to the second embodiment in FIG. 5, the third embodiment in FIG. 7, and the fourth embodiment in FIG. 9.

### Fifth Embodiment

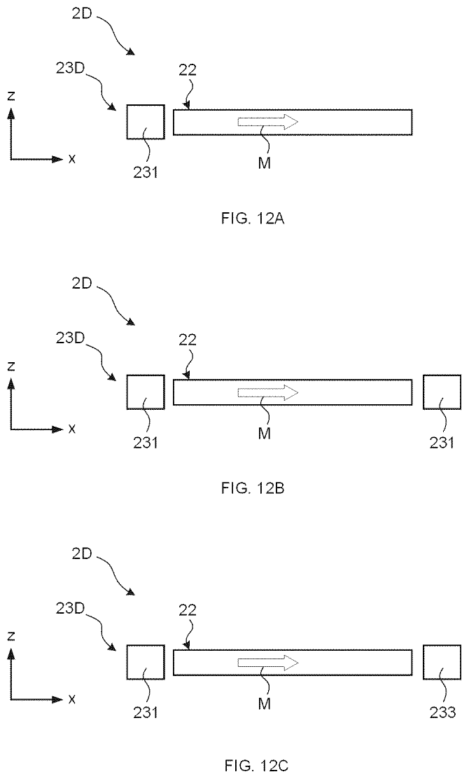

FIGS. 12A to 12C are schematic side views of a heat flow measuring device 2D according to a fifth embodiment. As shown in FIG. 12A, the heat flow measuring device 2D includes a thermoelectric conversion unit 22 and a magnetic field application unit 23D. The thermoelectric conversion unit 22 of the heat flow measuring device 2D is similar to the thermoelectric conversion unit 22 of the heat flow measuring device 2 in FIG. 2.

### <Magnetic Field Application Unit 23D>

The magnetic field application unit 23D includes at least one magnet 231 disposed on a side of the layered thermoelectric conversion unit 22. Thus, the thickness of the heat exchange portion of the heat flow measuring device 2D is kept small. Specifically, in an example in FIG. 12A, the magnet 231 is disposed to face or contact one end in an x-direction of the thermoelectric conversion unit 22. The direction of a magnetic field M applied by the magnet 231 intersects the thickness direction of the thermoelectric conversion unit 22.

As shown in FIG. 12B, the magnetic field application unit 23D may include two magnets 231 disposed to face or contact the two ends in the x-direction of the thermoelectric conversion unit 22. In other words, the magnetic field application unit 23D may include the two magnets 231 disposed such that the thermoelectric conversion unit 22 is sandwiched therebetween in a direction intersecting the thickness direction of the thermoelectric conversion unit 22 (specifically, in the x-direction, which is perpendicular to the thickness direction). This allows for stable generation of the magnetic field M in the direction intersecting the thickness direction of the thermoelectric conversion unit 22. The magnets 231 are the same as magnet 231 in FIG. 2 except for the shape.

As shown in FIG. 12C, in addition to the magnet 231, the magnetic field application unit 23D may include at least one soft magnetic portion 233 disposed on a side of the thermoelectric conversion unit 22. The soft magnetic portion 233 is disposed such that the thermoelectric conversion unit 22 is sandwiched between the soft magnetic portion 233 and the magnet 231 in the direction intersecting the thickness direction of the thermoelectric conversion unit 22 (specifically, in the x-direction, which is perpendicular to the thickness direction). In other words, the soft magnetic portion 233 faces or contacts the end opposite to the end faced or contacted by the magnet 231 of the ends in the x-direction of the thermoelectric conversion unit 22. The soft magnetic portion 233 is the same as the soft magnetic portions 233 in FIG. 7 except for the shape.

### Sixth Embodiment

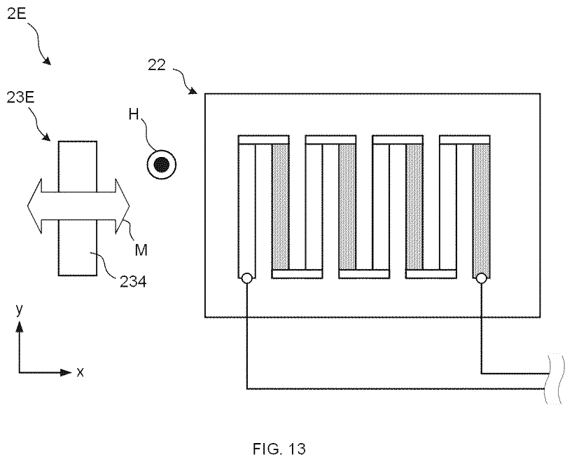

FIG. 13 is a schematic plan view of a heat flow measuring device 2E according to a sixth embodiment. As shown in FIG. 13, the heat flow measuring device 2E includes a thermoelectric conversion unit 22 and a magnetic field application unit 23E. The thermoelectric conversion unit 22 of the heat flow measuring device 2E is similar to the thermoelectric conversion unit 22 of the heat flow measuring device 2 in FIG. 2.

### <Magnetic Field Application Unit 23E>

The magnetic field application unit 23E includes a coil 234 configured to generate a magnetic field. This facilitates adjustment of the magnitude and direction of a magnetic field provided by the magnetic field application unit 23E. Specifically, the coil 234 is disposed on a side of the thermoelectric conversion unit 22 in a plan view. The axial direction of the coil 234 intersects the thickness direction of the thermoelectric conversion unit 22 and the direction of a heat flow H and is, specifically, parallel to a y-direction, which is perpendicular to the thickness direction. When receiving supply of a current, the coil 234 generates the magnetic field M that is to pass through the thermoelectric conversion unit 22. The direction of the magnetic field M is determined by the direction of the current supplied to the coil 234.

### 2. Hardware Configuration of Information Processing Device 4

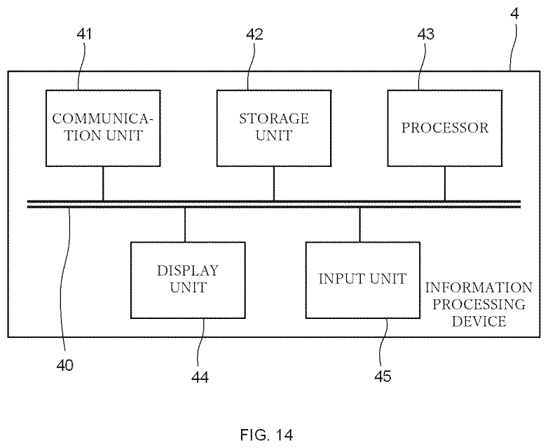

This section describes an example of the hardware configuration of the above information processing device 4. FIG. 14 is a block diagram showing the hardware configuration of the information processing device 4. The information processing device 4 includes a communication bus 40, a communication unit 41, a storage unit 42, a processor 43 as a controller, a display unit 44, and an input unit 45. These components are electrically connected through the communication bus 40 inside the information processing device 4.

### <Communication Unit 41>

While the communication unit 41 preferably uses wired communication means such as USB, IEEE 1394, Thunderbolt®, or wired LAN network communication, it may use wireless LAN network communication, mobile communication such as 3G, LTE, or 5G, BLUETOOTH® communication, or the like as necessary. Preferably, the communication unit 41 is able to use a set of these multiple communication means. That is, the information processing device 4 may transmit and receive various types of information to and from the outside through the communication unit 41 and any network.

### <Storage Unit 42>

The storage unit 42 is storing various types of information defined by the above description. The storage unit 42 may be embodied, for example, as a storage device such as a solid-state drive (SSD) for storing various programs or the like related to the information processing device 4 executed by the processor 43, or as memory such as random access memory (RAM) for storing temporarily required information (arguments, arrays, etc.) related to program calculations. The storage unit 42 is storing various programs, variables, and the like related to the information processing device 4 executed by the processor 43.

### <Processor 43>

The processor 43 processes and controls overall operation related to the information processing device 4. The processor 43 is, for example, a central processing unit (CPU) (not shown). The processor 43 implements various functions related to the information processing device 4 by reading a predetermined program stored in the storage unit 42. That is, when information processing by software stored in the storage unit 42 is specifically executed by the processor 43, which is an example of hardware, functional units included in the processor 43 are implemented. These will be described in more detail in the next section. Note that the processor 43 does not have to be a single processor but may include function-specific multiple processors 43. Or, the processor 43 may be a combination of these.

The display unit 44 may be contained in the housing of the information processing device 4 or may be externally attached thereto. The display unit 44 displays a graphical user interface (GUI) screen operable by a user. It is preferable to select a display device such as a CRT display, a liquid crystal display, an organic EL display, or a plasma display as the display unit 44 in accordance with the type of information processing device 4.

### <Input Unit 45>

The input unit 45 may be contained in the housing of the information processing device 4 or may be externally attached thereto. For example, the input unit 45 may be embodied as a touchscreen integrated with the display unit 44. If the input unit 45 is a touchscreen, the user can make inputs by performing a tap operation, a swipe operation, or the like thereon. Of course, the input unit 45 may be a switch button, mouse, QWERTY keyboard, or the like in place of a touchscreen. That is, the input unit 45 receives operation inputs made by the user. The inputs are transferred to the processor 43 as instruction signals through the communication bus 40, and the processor 43 performs predetermined control or calculation as necessary.

### 3. Functional Configuration of Information Processing Device 4

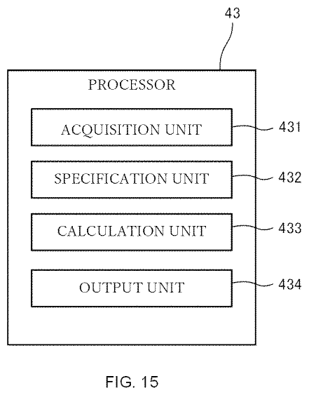

This section describes an example of the functional configuration of the above processor 43. FIG. 15 is a diagram showing an example of the functional units included in the processor 43.

The processor 43 includes an acquisition unit 431, a specification unit 432, a calculation 433, and an output unit 434.

### <Acquisition Unit 431>

The acquisition section 431 is configured to acquire information from the power measuring device 3. For example, the acquisition unit 431 is configured to acquire the thermoelectromotive forces V generated by the first thermoelectric conversion devices 22a and second thermoelectric conversion devices 22b of the heat flow measuring device 2 through the power measuring device 3. The power measuring device 3 converts the thermoelectromotive forces V outputted from the heat flow measuring device 2 into information that can be acquired by the acquisition unit 431.

The acquisition unit 431 is also configured to acquire various types of information by reading various types of information stored in a storage area, which is at least a part of the storage unit 42, and writing the read information into a work area, which is at least a part of the storage unit 42. The storage area is, for example, an area of the storage unit 42 embodied as a storage device such as a SSD. The work area is, for example, an area embodied as memory such as RAM.

### <Specification Unit 432>

The specification unit 432 is configured to receive specification from the user, any other functional unit, or any other device. For example, the specification unit 432 receives any specification based on an input made to the input unit 45.

### <Calculation Unit 433>

The calculation unit 433 is configured to perform various calculations on the basis of various types of information, such as the information acquired by the acquisition section 431 and the specification received by the specification unit 432. For example, the calculation unit 433 calculates the first electromotive forces V1 or the second electromotive forces V2 on the basis of the thermoelectromotive forces V acquired by the acquisition unit 431.

### <Output Unit 434>

The output unit 434 is configured to output various types of information. An external device (not shown) can perform various types of control on the basis of the information outputted from the output unit 434. For example, the external device may estimate the temperature of the object to be measured on the basis of the information outputted from the output unit 434 and control the driving mode of the object to be measured on the basis of the estimated temperature. The output unit 434 can present this information to the user through the display unit 44 of the information processing device 4 or any other device. In this case, the output unit 434 may control the display unit 44 of the information processing device 4 so that the display unit 34 displays visual information such as screens, images including still or moving images, icons, or messages. The output unit 434 may generate only rendering information for displaying visual information on the information processing device 4. The output unit 434 may present the outputted information to the user not through the information processing device 4 or any other device.

### 4. Information Processing

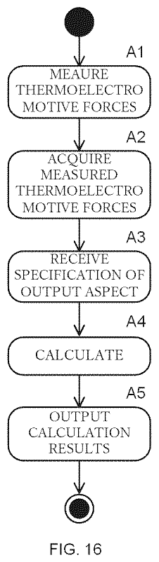

This section describes information processing performed by the above heat flow measuring system 1. FIG. 16 is an activity diagram showing an example of the flow of information processing performed by the heat flow measuring system 1. The information processing may include any exception handling (not shown). The exception handling includes interruption of the information processing and omission of each process. Selection or input in the information processing may be performed on the basis of a user operation, or automatically without depending on a user operation.

### [Activity A1]

First, in activity A1, the power measuring device 3 measures the thermoelectromotive forces V outputted from the heat flow measuring device 2. Thus, the power measuring device 3 acquires the thermoelectromotive forces V of the first thermoelectric conversion devices 22a included in the heat flow measuring device 2 and the thermoelectromotive forces V of the second thermoelectric conversion devices 22b included in the heat flow measuring device 2. The power measuring device 3 then outputs the acquisition results to the information processing device 4. For example, the power measuring device 3 outputs the measured values themselves of the thermoelectromotive forces V of the first thermoelectric conversion devices 22a and second thermoelectric conversion devices 22b. Note that the power measuring device 3 may output the thermoelectromotive forces V in any form. For example, the power measuring device 3 may output the average value of the thermoelectromotive forces V of the first thermoelectric conversion devices 22a and the average value of the thermoelectromotive forces V of the second thermoelectric conversion devices 22b. In short, the power measuring device 3 outputs the measurement results such that the thermoelectromotive forces V corresponding to the first thermoelectric conversion devices 22a and the thermoelectromotive forces V corresponding to the second thermoelectric conversion devices 22b can be distinguished from each other.

### [Activity A2]

The process then proceeds to activity A2. The acquisition unit 431 acquires the thermoelectromotive forces V of the first thermoelectric conversion devices 22a and the thermoelectromotive forces V of the second thermoelectric conversion devices 22b measured by the power measuring device 3 in activity A1. Note that the thermoelectromotive forces V measured by the power measuring device 3 do not have to be the values themselves of the thermoelectromotive forces V outputted from the measuring terminals 224 of the thermoelectric conversion unit 22 but may be the values obtained by subjecting the values of the thermoelectromotive forces V measured by the power measuring device 3 to the above arbitrary process.

### [Activity A3]

The process then proceeds to activity A3. The specification unit 432 receives specification related to calculation of a voltage value. Note that the voltage value is not limited to the value itself of a voltage but may be a value uniquely corresponding to the voltage, such as the value of a current flowing through a certain resistor or power consumption.

### [Activity A4]

The process then proceeds to activity A4. The calculation unit 433 calculates a value corresponding to the specification in activity A3 on the basis of the thermoelectromotive forces V of the first thermoelectric conversion devices 22a and the thermoelectromotive forces V of the second thermoelectric conversion devices 22b acquired in activity A2 and the specification received in activity A3. For example, the calculation unit 433 subtracts the thermoelectromotive forces V=−V1+V2 of the second thermoelectric conversion devices 22b from the thermoelectromotive forces V=V1+V2 of the first thermoelectric conversion devices 22a and divides the subtraction results by 2. In this way, the calculation unit 433 calculates the value of V1 as a first voltage value.

The calculation unit 433 may add the thermoelectromotive forces V=−V1+V2 of the second thermoelectric conversion devices 22b to the thermoelectromotive forces V=V1+V2 of the first thermoelectric conversion devices 22a and divide the addition results by 2. In this way, the calculation unit 433 calculates the value of V2 as a second voltage value.
Note that the calculation unit 433 may calculate these voltage values not in accordance with any specification.

### [Activity A5]

The process then proceeds to activity A5. The output unit 434 outputs the calculation results obtained in activity A4. In the present embodiment, the output unit 434 outputs the voltage value corresponding to the specification received in activity A3.

The outputted voltage value is used, for example, to control an external device. Such a voltage value corresponds to the in-plane component or perpendicular component of the heat gradient and therefore contains information on the temperature of the object to be measured and changes in the temperature. For this reason, the outputted voltage value can be used particularly to perform control in accordance with the temperature of the object to be measured. The outputted voltage value may be used to detect light, a chemical, or the like.

### 5. Heat Flow Measuring Method

This section describes a heat flow measuring method using the heat flow measuring system 1. The heat flow measuring method includes a signal acquisition step. The signal acquisition step is a step of acquiring an electrical signal outputted from the thermoelectric conversion unit 22 with a magnetic field in a given direction being applied to the thermoelectric conversion unit 22. This electrical signal is a signal obtained by converting, by the thermoelectric conversion unit 22, a heat gradient generated by heat exchange with the object to be measured, on the basis of the anomalous Nernst effect. Such a magnetic field in the given direction suppresses changes in the sensitivity of the heat gradient due to magnetization of the thermoelectric conversion unit 22 caused by a disturbing magnetic field. This reduces the effect of noise on the thermoelectric conversion unit 22 and improves the accuracy of detection of a heat flow.

### 6. Others

The above aspect of the heat flow measuring system 1 is only illustrative and is not limiting.

The thermoelectric conversion unit 22 and magnetic field application unit 23 do not necessarily have to be formed in a layered shape. For example, the thermoelectric conversion unit 22 and magnetic field application unit 23 may be each formed in the shape of a block with a large thickness.

While, in the present embodiment, the power measuring device 3 and information processing device 4 are separate devices, these devices may be integrated. The power measuring device 3 may include the functional units (the acquisition unit 431, specification unit 432, calculation unit 433, and output unit 434) of the information processing device 4. That is, the above information processing may be performed by the power measuring device 3.

In the above heat flow measuring system 1, the calculation unit 433 does not have to perform calculations using digital signals but may perform calculations using an analog circuit such as an addition circuit, or a combination of these.

In the present embodiment, the power measuring device 3 may be disposed on the substrate (e.g., the insulator 21) of the heat flow measuring device 2. In other words, the heat flow measuring device 2 and power measuring device 3 may be disposed on-board on the single substrate.

The heat flow measuring device 2 and power measuring device 3 may be configured to wirelessly communicate with each other. In other words, the power measuring device 3 may measure the thermal thermoelectromotive forces V through wireless communication with the heat flow measuring device 2. In this case, the heat flow measuring device 2 does not have to include the port 24.

The external devices of the heat flow measuring device 2, such as the power measuring device 3 and information processing device 4, which perform the above information processing, may be on-premise or on cloud. For example, on-cloud external devices may provide the above functions or processing in the form of SaaS (Software as a Service) or cloud computing.

While, in the above embodiment, the power measuring device 3 and information processing device 4 perform various types of storage and control, other multiple external devices may be used in place of the power measuring device 3 and information processing device 4. In other words, various types of information and programs may be distributed and stored in other multiple external devices using a blockchain technology or the like.

The above embodiment is not limited to the heat flow measuring system 1 but may be an information processing method or an information processing program. The information processing method includes the step performed by the heat flow measuring system 1. The information processing program causes at least one computer to perform the step performed by the heat flow measuring system 1.

The above heat flow measuring system 1 and the like may be provided in aspects below.

(1) A heat flow measuring apparatus comprising: a thermoelectric conversion unit configured to convert a heat gradient generated by heat exchange with an object to be measured into an electrical signal, on the basis of the anomalous Nernst effect; and a magnetic field application unit configured to apply a magnetic field in a given direction to the thermoelectric conversion unit.

According to such a configuration, the magnetic field provided by the magnetic field application unit suppresses changes in the sensitivity of the heat gradient due to the magnetization of the thermoelectric conversion unit caused by the disturbing magnetic field. This reduces the effect of noise on the thermoelectric conversion unit and improves the accuracy of detection of a heat flow.

(2) The heat flow measuring apparatus according to (1), wherein the magnetic field application unit comprises at least one magnet stacked on the thermoelectric conversion unit.

According to such a configuration, the magnetic field application unit and the thermoelectric conversion unit 22 are integrated. This downsizes the heat flow measuring device and makes it easy to handle the heat flow measuring device.

(3) The heat flow measuring apparatus according to (2), further comprising an insulator disposed between the thermoelectric conversion unit and the at least one magnet.

According to such a configuration, the thermoelectric conversion unit 22 and the magnet are bonded together by the insulator. That is, the heat flow measuring device can be easily produced.

(4) The heat flow measuring apparatus according to (2) or (3), wherein the magnetic field application unit further comprises at least one high heat conductor aligned with the at least one magnet in an alignment direction, wherein the alignment direction is a direction intersecting a direction in which the at least one magnet is stacked on the thermoelectric conversion unit, and the at least one high heat conductor has a higher thermal conductivity than the at least one magnet.

According to such a configuration, the high heat conductor suppresses a reduction in the efficiency of heat exchange with the object to be measured while the magnet applies the magnetic field.

(5) The heat flow measuring apparatus according to (4), wherein: the magnetic field application unit comprises a plurality of magnets as the at least one magnet and a plurality of high heat conductors as the at least one high heat conductor, and the magnets and the high heat conductors are disposed alternately in the alignment direction.

According to such a configuration, both the effect of reducing noise due to the application of the magnetic field and the effect of suppressing a reduction in the heat exchange efficiency are promoted.

(6) The heat flow measuring apparatus according to any one of (2) to (5), wherein the magnetic field application unit further comprises at least one soft magnetic portion aligned with the at least one magnet in an alignment direction, wherein the alignment direction is a direction intersecting a direction in which the at least one magnet is stacked on the thermoelectric conversion unit, and the at least one soft magnetic portion contains a soft magnetic material as a main component.

According to such a configuration, the soft magnetic portion suppresses a reduction in the efficiency of heat exchange with the object to be measured while the magnet applies the magnetic field.

(7) The heat flow measuring apparatus according to (6), wherein: the magnetic field application unit comprises a plurality of magnets as the at least one magnet and a plurality of soft magnetic portions as the at least one soft magnetic portion, and the magnets and the soft magnetic portions are disposed alternately in the alignment direction.

According to such a configuration, both the effect of reducing noise due to the application of the magnetic field and the effect of suppressing a reduction in the heat exchange efficiency are promoted.

(8) The heat flow measuring apparatus according to (2), wherein the magnetic field application unit further comprises: at least one high heat conductor aligned with the at least one magnet in an alignment direction; and at least one soft magnetic portion aligned with the at least one magnet in the alignment direction, wherein: the alignment direction is a direction intersecting a direction in which the at least one magnet is stacked on the thermoelectric conversion unit, the at least one high heat conductor has a higher thermal conductivity than the at least one magnet, and the at least one soft magnetic portion contains a soft magnetic material as a main component.

According to such a configuration, the high heat conductor and soft magnetic portion suppress a reduction in the efficiency of heat exchange with the object to be measured while the magnet applies the magnetic field.

(9) The heat flow measuring apparatus according to (8), wherein the magnetic field application unit comprises a plurality of magnets as the at least one magnet, a plurality of high heat conductors as the at least one high heat conductor, and a plurality of soft magnetic portions as the at least one soft magnetic portion, and the magnets, the high heat conductors, and the soft magnetic portions are disposed alternately in the alignment direction.

According to such a configuration, both the effect of reducing noise due to the application of the magnetic field and the effect of suppressing a reduction in the heat exchange efficiency are promoted.

(10) The heat flow measuring apparatus according to any one of (1) to (9), wherein: the thermoelectric conversion unit is a layered member, and the magnetic field application unit is a layered member stacked on the thermoelectric conversion unit in a thickness direction of the thermoelectric conversion unit.

Such a configuration reduces the thickness of the heat flow measuring device, allowing the heat flow measuring device to be used for a variety of purposes.

(11) The heat flow measuring apparatus according to (1), wherein: the thermoelectric conversion unit is a layered member, and the magnetic field application unit comprises at least one magnet disposed on a side of the thermoelectric conversion unit.

Such a configuration reduces the thickness of the heat exchange portion of the heat flow measuring device.

(12) The heat flow measuring apparatus according to (1), wherein the magnetic field application unit comprises a coil configured to generate the magnetic field.

Such a configuration facilitates adjustment of the magnitude and direction of the magnetic field provided by the magnetic field application unit.

(13) A heat flow measuring method, comprising: a signal acquisition step of acquiring an electrical signal outputted from a thermoelectric conversion unit with a magnetic field in a given direction being applied to the thermoelectric conversion unit, the electrical signal being a signal obtained by converting, by the thermoelectric conversion unit, a heat gradient generated by heat exchange with an object to be measured, on the basis of the anomalous Nernst effect.

According to such a configuration, the magnetic field in the given direction suppresses changes in the sensitivity of the heat gradient due to the magnetization of the thermoelectric conversion unit caused by the disturbing magnetic field. This reduces the effect of noise on the thermoelectric conversion unit and improves the accuracy of detection of a heat flow.

Of course, these aspects are not limiting.

Finally, while the various embodiments according to the present disclosure have been described above, the embodiments are only illustrative and are not intended to limit the scope of the invention. The novel embodiments can be carried out in other various forms, and various omissions, replacements, or changes can be made thereto without departing from the gist of the invention.

The embodiments and modifications thereof are included in the scope and gist of the present invention, as well as included in the scope of the invention set forth in the claims and equivalents thereof.

1. A heat flow measuring apparatus comprising:
a thermoelectric conversion unit configured to convert a heat gradient generated by heat exchange with an object to be measured into an electrical signal, on the basis of the anomalous Nernst effect; and
a magnetic field application unit configured to apply a magnetic field in a given direction to the thermoelectric conversion unit.

2. The heat flow measuring apparatus according to claim 1, wherein
the magnetic field application unit comprises at least one magnet stacked on the thermoelectric conversion unit.

3. The heat flow measuring apparatus according to claim 2, further comprising
an insulator disposed between the thermoelectric conversion unit and the at least one magnet.

4. The heat flow measuring apparatus according to claim 2, wherein
the magnetic field application unit further comprises at least one high heat conductor aligned with the at least one magnet in an alignment direction, wherein the alignment direction is a direction intersecting a direction in which the at least one magnet is stacked on the thermoelectric conversion unit, and the at least one high heat conductor has a higher thermal conductivity than the at least one magnet.

5. The heat flow measuring apparatus according to claim 4, wherein:
the magnetic field application unit comprises a plurality of magnets as the at least one magnet and a plurality of high heat conductors as the at least one high heat conductor, and
the magnets and the high heat conductors are disposed alternately in the alignment direction.

6. The heat flow measuring apparatus according to claim 2, wherein
the magnetic field application unit further comprises at least one soft magnetic portion aligned with the at least one magnet in an alignment direction, wherein the alignment direction is a direction intersecting a direction in which the at least one magnet is stacked on the thermoelectric conversion unit, and the at least one soft magnetic portion contains a soft magnetic material as a main component.

7. The heat flow measuring apparatus according to claim 6, wherein:
the magnetic field application unit comprises a plurality of magnets as the at least one magnet and a plurality of soft magnetic portions as the at least one soft magnetic portion, and
the magnets and the soft magnetic portions are disposed alternately in the alignment direction.

8. The heat flow measuring apparatus according to claim 2, wherein the magnetic field application unit further comprises:
at least one high heat conductor aligned with the at least one magnet in an alignment direction; and
at least one soft magnetic portion aligned with the at least one magnet in the alignment direction, wherein:
the alignment direction is a direction intersecting a direction in which the at least one magnet is stacked on the thermoelectric conversion unit,
the at least one high heat conductor has a higher thermal conductivity than the at least one magnet, and
the at least one soft magnetic portion contains a soft magnetic material as a main component.

9. The heat flow measuring apparatus according to claim 8, wherein
the magnetic field application unit comprises a plurality of magnets as the at least one magnet, a plurality of high heat conductors as the at least one high heat conductor, and a plurality of soft magnetic portions as the at least one soft magnetic portion, and
the magnets, the high heat conductors, and the soft magnetic portions are disposed alternately in the alignment direction.

10. The heat flow measuring apparatus according to claim 1, wherein:
the thermoelectric conversion unit is a layered member, and
the magnetic field application unit is a layered member stacked on the thermoelectric conversion unit in a thickness direction of the thermoelectric conversion unit.

11. The heat flow measuring apparatus according to claim 1, wherein:
the thermoelectric conversion unit is a layered member, and
the magnetic field application unit comprises at least one magnet disposed on a side of the thermoelectric conversion unit.

12. The heat flow measuring apparatus according to claim 1, wherein
the magnetic field application unit comprises a coil configured to generate the magnetic field.

13. A heat flow measuring method, comprising:
a signal acquisition step of acquiring an electrical signal outputted from a thermoelectric conversion unit with a magnetic field in a given direction being applied to the thermoelectric conversion unit, the electrical signal being a signal obtained by converting, by the thermoelectric conversion unit, a heat gradient generated by heat exchange with an object to be measured, on the basis of the anomalous Nernst effect.
